(19) United States
(12) Patent Application Publication
(10) Pub. No.: US 2020/0393492 A1
(43) Pub. Date: Dec. 17, 2020

(54) TEST SOCKET, PROBE CARD AND TEST DEVICE

(71) Applicant: Samsung Electronics Co., Ltd., Suwon-si (KR)

(72) Inventors: Semi Ko, Seoul (KR); Jaikie Kim, Suwon-si (KR); Eunsun Kang, lmsil-gun (KR); Youngjin Kim, Seoul (KR); Taejeong Kim, Ansan-si (KR); Taejoon Kim, Seongnam-si (KR); Jeongsik Lim, Hwaseong-si (KR)

(21) Appl. No.: 16/777,168

(22) Filed: Jan. 30, 2020

(30) Foreign Application Priority Data
Jun. 14, 2019 (KR) 10-2019-0070948

(51) Int. Cl. G01R 1/04; G01R 1/073; G01R 31/26

(52) U.S. Cl. CPC G01R 1/0408; G01R 31/2601; G01R 1/07342

(57) ABSTRACT

A test socket includes a housing and a mounting portion extending from the housing and including an accommodation space configured to mount a semiconductor device thereon. A lower surface of the mounting portion includes a plurality of holes corresponding to a plurality of pins included in the semiconductor device, the plurality of holes being configured to align the plurality of pins of the semiconductor device with a plurality of socket pins of a printed circuit board. The housing and the mounting portion include the same insulating material.

### CROSS-REFERENCE TO RELATED APPLICATION(S)

This application claims benefit of priority to Korean Patent Application No. 10-2019-0070948 filed on Jun. 14, 2019 in the Korean Intellectual Property Office, the disclosure of which is incorporated herein by reference in its entirety.

### BACKGROUND

The present inventive concept relates generally to semiconductor device testing and, more particularly, to a test socket, a probe card, and a test device for use in semiconductor device testing.

Semiconductor devices mounted on electronic devices may be shipped on a wafer level, a package level, and the like, and a test process using printed circuit boards on which the semiconductor devices are mounted in the electronic devices may also be performed. A semiconductor device may be connected to a circuit board that processes an electrical signal through a test socket to input an electrical signal to the semiconductor device in the test process and to obtain an electrical signal output by the semiconductor device. The test socket may be formed of an insulating material, and may have a plurality of holes into which a plurality of pins formed in the semiconductor device are inserted.

### SUMMARY

An aspect of the present inventive concept is to provide a test socket, a probe card, and a test device, in which accuracy and efficiency of a test process for a semiconductor device may be improved by reducing signal loss or the like that may occur in a test process for a semiconductor device when processing high frequency signals and by improving impedance matching. According to an aspect of the present inventive concept, a test socket includes a housing and a mounting portion extending from the housing and comprising an accommodation space configured to mount a semiconductor device thereon. A lower surface of the mounting portion comprises a plurality of holes corresponding to a plurality of pins included in the semiconductor device, the plurality of holes being configured to align the plurality of pins of the semiconductor device with a plurality of socket pins of a printed circuit board. The housing and the mounting portion comprise the same insulating material. According to an aspect of the present inventive concept, a probe card includes a test socket comprising a material having a dielectric constant of 3.0 or more and comprising a plurality of accommodation spaces separated from each other by a partition structure to accommodate a plurality of semiconductor devices, respectively, a lower surface of each of the plurality of accommodation spaces having a plurality of holes corresponding to a plurality of pins included in each of the plurality of semiconductor devices, and a main circuit board on one surface of the test socket and electrically connected to a test device, the main circuit board including a plurality of probe pins extending therefrom into the plurality of holes included in the plurality of accommodation spaces, respectively.

According to an aspect of the present inventive concept, a test device includes a controller configured to generate a signal for testing of a test object having at least one semiconductor device, a test socket comprising bakelite and comprising at least one accommodation space configured to accommodate the at least one semiconductor device, the at least one accommodation space having a plurality of test pins configured to output the signal to the at least one semiconductor device, and a cover socket configured to apply pressure to the at least one semiconductor device.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1 and 2 are schematic drawings illustrating an electronic device to which a test process using a test socket according to example embodiments of the present inventive concept may be applied;

FIG. 3 is a flowchart illustrating a test process using a test socket according to example embodiments of the present inventive concept;

FIGS. 4 to 12 are diagrams illustrating a test process using a test socket according to example embodiments of the present inventive concept;

FIGS. 13 to 15 are diagrams illustrating a test socket according to example embodiments of the present inventive concept;

FIG. 16 is a graph illustrating the effect of a test process using a test socket according to example embodiments of the present inventive concept;

FIG. 17 is a block diagram schematically illustrating a test device according to example embodiments of the present inventive concept;

FIGS. 18 and 19 are schematic drawings illustrating a probe card according to example embodiments of the present inventive concept;

FIG. 20 is a drawing illustrating a test process using a probe card according to example embodiments of the present inventive concept;

FIG. 21 is a diagram schematically illustrating a test device according to example embodiments of the present inventive concept; and

FIGS. 22 to 24 are drawings illustrating a test process performed by a test device according to example embodiments of the present inventive concept.

### DETAILED DESCRIPTION

Hereinafter, example embodiment of the present inventive concept will be described in detail with reference to the accompanying drawings. The same reference numerals are used for the same constituent elements in the drawings, and redundant description of the same constituent elements will be omitted.

As used herein, the term “and/or” includes any and all combinations of one or more of the associated listed items. It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It is noted that aspects described with respect to one embodiment may be incorporated in different embodiments although not specifically described relative thereto. That is, all embodiments and/or features of any embodiments can be combined in any way and/or combination.

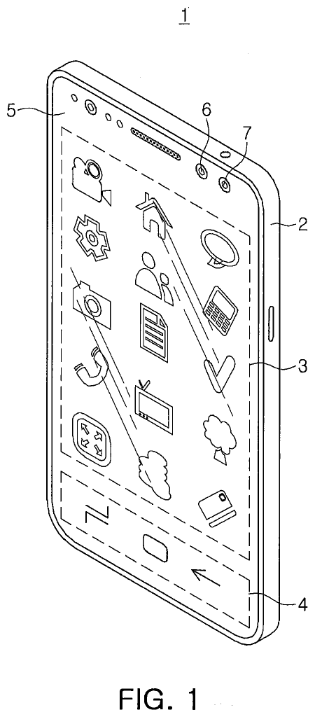

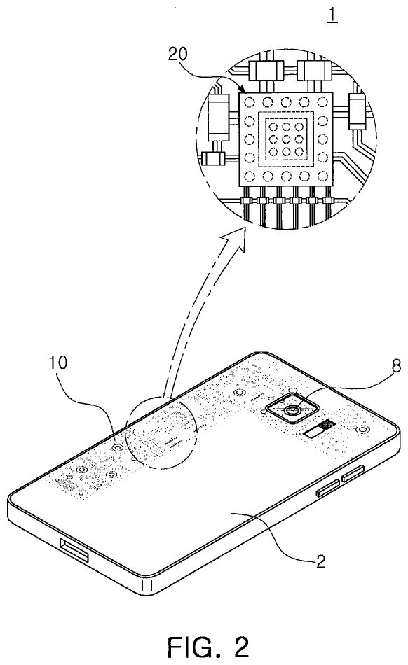

Referring to FIGS. 1 and 2, an electronic device 1 according to example embodiments of the inventive concept may be a mobile device having a communication function. A test process using a test socket according to example embodiments described herein is not limited to mobile devices, but may also be applied to various other electronic devices.

Referring to FIG. 1, an electronic device 1 according to some example embodiments may include a case 2, a display 5 provided on the front of the case 2, front cameras 6 and 7, and the like. The display 5 may be disposed on the front surface of the case 2 and may cover substantially the entire front surface of the case 2. For example, most of the front surface of the case 2 may be allocated to the display 5.

The front cameras 6 and 7 may comprise a plurality of front cameras 6 and 7 according to some example embodiments. The plurality of front cameras 6 and 7 may have different angles of view, pixel numbers, and aperture values, and the user may capture various types of images using the plurality of front cameras 6 and 7. As an example, at least one of the plurality of front cameras 6 and 7 may be used for obtaining biometric information by recognizing a face, an iris, or the like, of the user.

Referring to FIG. 2, the electronic device 1 may include the case 2, a rear camera 8, and the like. Unlike the example embodiment illustrated in FIG. 2, the rear camera 8 may include a plurality of cameras in other embodiments. When the rear camera 8 includes a plurality of cameras, the plurality of cameras may have different pixel numbers, angles of view, aperture values, and the like.

Inside the case 2 of the electronic device 1, various components may be mounted as illustrated in FIG. 2. The components may be configured to implement various functions of the electronic device 1 and may include a semiconductor device, a circuit board, a battery, circuit devices, and the like. For example, a circuit board 10 may be mounted in the case 2 of the electronic device 1, and a semiconductor device 20 may be mounted on the circuit board 10. The semiconductor device 20 may be connected to other semiconductor devices, circuit devices, batteries, and the like through the circuit board 10 to exchange data and/or power therewith.

In a manufacturing process of the electronic device 1, a test process of verifying the semiconductor device 20 mounted on the electronic device 1 may be performed. The test process of verifying the semiconductor device 20 may be variously performed in a wafer operation, a package operation, and a subsequent operation after mounting the circuit board 10, and the like according to different embodiments of the inventive concept.

In an example embodiment, the test process for the semiconductor device 20 may be performed by mounting the semiconductor device 20 and inputting an electrical signal used for the test to a test socket mounted on a test printed circuit board for the test process. For example, in the test process, an intermediate board to electrically connect the test printed circuit board and the semiconductor device 20 may be disposed between the test socket on which the semiconductor device 20 is mounted and the test printed circuit board. However, as the operating speed of the semiconductor device 20 increases and the frequency band used in the communication function provided by the semiconductor device 20 increases, the accuracy of the test process may be impaired due to signal loss due to the presence of the intermediate board, impedance matching deterioration, or the like.

In some example embodiments, the test apparatus for performing a test process may comprise a test socket to directly connect the semiconductor device 20 and a test printed circuit board in a pin-to-pin manner without an intermediate board, a probe card including the same, and a test device. For example, the semiconductor device 20 and the test printed circuit board may be directly connected by mounting the semiconductor device 20 on the test socket without a separate intermediate board. Therefore, signal loss between the semiconductor device 20 and the test printed circuit board may be reduced, impedance may be more accurately matched, and reliability and efficiency of the test process may be improved.

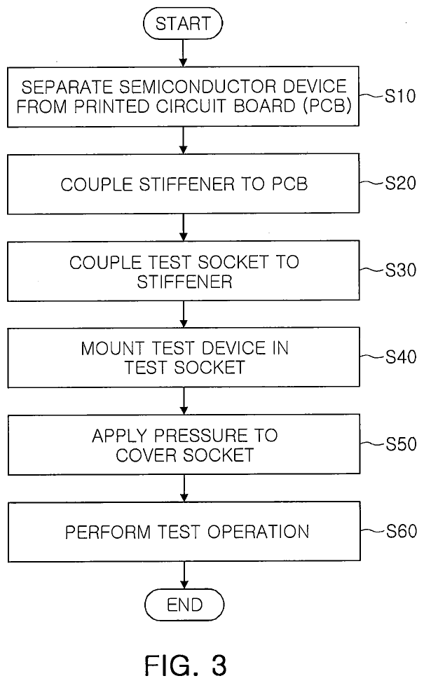

FIG. 3 is a flowchart illustrating a test process using a test socket according to some example embodiment of the inventive concept.

A test process, according to some example embodiments of the inventive concept illustrated with reference to FIG. 3, may correspond to a mounting test in which a test socket is mounted on a circuit board of an electronic device and semiconductor devices are mounted in a test socket. Referring to FIG. 3, the test process may be started by separating a semiconductor device from a printed circuit board (S10). In operation S10, the printed circuit board may be a circuit board mounted inside the electronic device. To perform the mounting test, when there is a semiconductor device mounted on the printed circuit board, the semiconductor device may be separated from the printed circuit board.

When the semiconductor device is separated, a stiffener may be coupled to the printed circuit board (S20). The stiffener is a structure coupled to the printed circuit board, or a housing of an electronic device equipped with the printed circuit board, and may include an accommodation space in which a test socket is accommodated. For example, in the accommodation space, a socket region of the printed circuit board on which the semiconductor device is mounted may be exposed externally. The stiffener may be formed of a material having a predetermined level or more of strength, such as a metal, and may be coupled to the printed circuit board in such a manner that it may be separated by a predetermined distance or more from an upper surface of the printed circuit board on which the circuit devices are disposed.

When the stiffener and the printed circuit board are coupled, the test socket may be coupled to the stiffener (S30). The test socket may be formed of an insulating material, and may have a shape corresponding to the accommodation space provided in the stiffener. For example, in some embodiments, the test socket may be formed of bakelite having suitable thermosetting properties and strength. In other embodiments, the test socket may be formed of an insulating material having a dielectric constant of 3.0 or more. When the test socket is coupled to the stiffener, the semiconductor device may be mounted in the test socket (S40).

The test socket may include a mounting portion in which the semiconductor device may be mounted. As an example, a plurality of holes corresponding to a plurality of pins included in the semiconductor device may be provided in a lower surface of the mounting portion. In the plurality of holes provided in the lower surface of the mounting portion, the plurality of pins included in the semiconductor device and a plurality of socket pins formed in the socket region of the printed circuit board (PCB) may be connected in a pin-to-pin manner.

Pressure may be applied to a cover socket (S50) to connect the plurality of pins included in the semiconductor device and the plurality of socket pins formed in the socket region of the PCB. The cover socket is a device that is coupled to the stiffener, and, in the test process, the operator may apply pressure to the semiconductor device using the cover socket. By the pressure applied to the semiconductor device, the plurality of pins of the semiconductor device and the plurality of socket pins of the printed circuit board may be coupled to each other in the plurality of holes provided in the lower surface of the mounting portion of the test socket. Therefore, the same effect as that in which the semiconductor device is mounted in the socket region of the printed circuit board may be obtained.

When the semiconductor device and the printed circuit board are connected, a test operation may be performed (S60). As an example, the test operation may be executed by inputting a predetermined test signal to the printed circuit board and obtaining a result signal that is output by the semiconductor device in response to the test signal. In an example embodiment, a semiconductor device may be directly mounted on a test socket, which is mounted on a printed circuit board. By directly connecting the semiconductor device and the test socket without using a separate intermediate board, signal loss may be reduced and impedance may be more accurately matched. Therefore, even when the semiconductor device processes a signal of a relatively high frequency band, the test process may be performed with sufficient accuracy. In addition, the test process may be performed using only a test socket without a separate intermediate board, thereby reducing the cost of a test process.

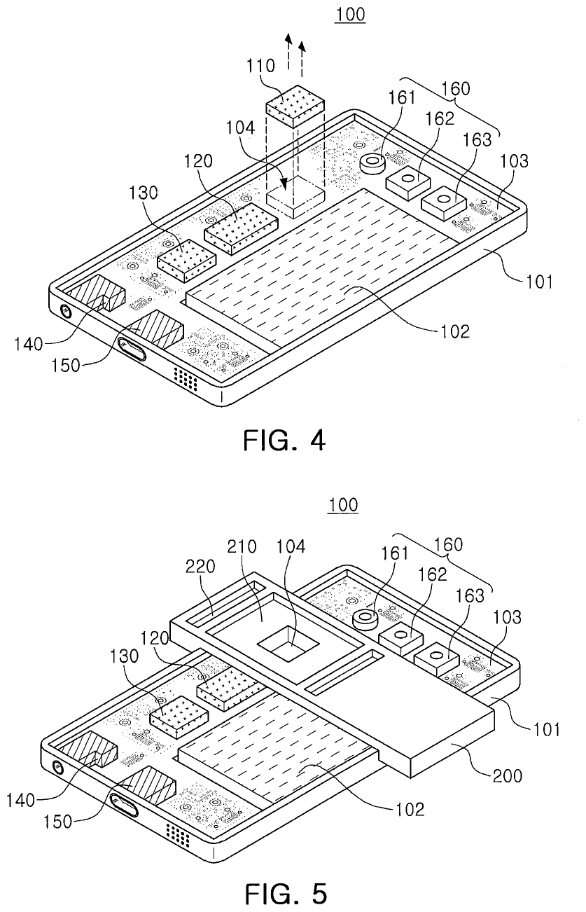

FIGS. 4 to 12 are diagrams illustrating a test process using a test socket according to some example embodiments of the inventive concept.

A test process according to some example embodiments of the inventive concept illustrated in FIGS. 4 to 12 may comprise a mounting test performed using a circuit board 103 mounted in an electronic device 100. In an example embodiment illustrated in FIGS. 4 to 12, the electronic device 100 may be a mobile device such as a smart phone or the like, and may include a housing 101, a battery 102, a circuit board 103, and the like. A plurality of semiconductor devices 110 to 130 may be mounted on the circuit board 103, and interfaces 140 and 150 and cameras 161 to 163 (cameras 160) may be disposed thereon. In addition, circuit wires, circuit devices and the like may be provided on the circuit board 103 to connect the plurality of semiconductor devices 110 to 130, the interfaces 140 and 150 and the cameras 160 to each other.

Referring to FIG. 4, at least one of the plurality of semiconductor devices 110 to 130 may be separated from the circuit board 103. In the example embodiment illustrated in FIG. 4, the semiconductor device, for example, a first semiconductor device 110, may be separated from the circuit board 103. Because the first semiconductor device 110 is separated from the circuit board 103, a first socket region 104 of the circuit board 103 in which the first semiconductor device 110 is mounted may be exposed externally. The first socket region 104 may include the plurality of socket pins electrically connected to the plurality of pins included in the first semiconductor device 110.

Next, referring to FIG. 5, a stiffener 200 may be coupled to the electronic device 100. As described above, the stiffener 200 may be formed of a material having a certain level or more of strength, for example, a metal material or the like. In an example embodiment, the stiffener 200 may be coupled to the housing 101 of the electronic device 100.

The stiffener 200 may include an accommodation space 210 to which a test socket is coupled. The accommodation space 210 may be formed to have a shape corresponding to the shape of the test socket to be coupled to the stiffener 200, and the first socket region 104 may be exposed in the accommodation space 210. The first socket region 104 may be a region in which the first semiconductor device 110 has been mounted and then separated from the circuit board 103 in operation S10 described with reference to FIG. 4.

The stiffener 200 may include a coupling groove 220 formed adjacent to the accommodation space 210. A cover socket may be coupled to the coupling groove 220, to connect the semiconductor device to the circuit board 103 by applying pressure to the semiconductor device that is a test target. In the example embodiment illustrated in FIG. 5, the coupling groove 220 is provided in both sides of the accommodation space 210, but the coupling groove 220 may be also formed in the stiffener 200 in a different form in other embodiments of the inventive concept.

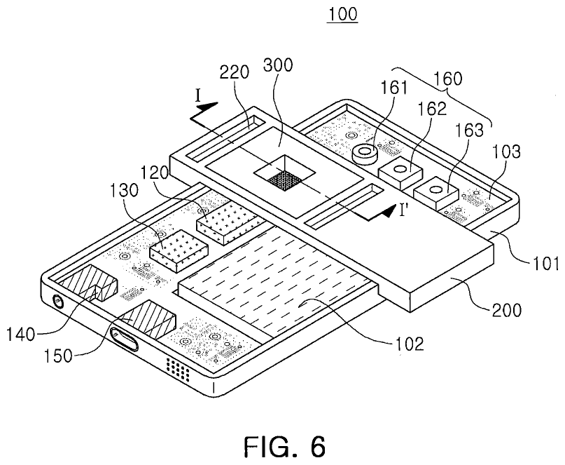

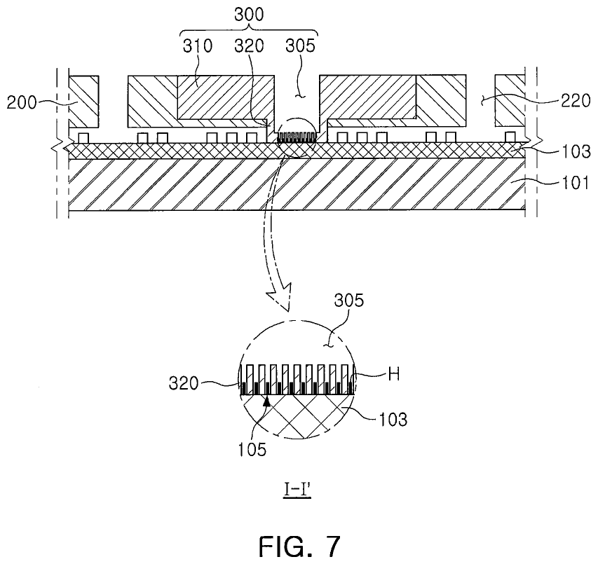

Referring to FIG. 6, a test socket 300 may be mounted in the accommodation space 210 of the stiffener 200. The test socket 300 may have a shape corresponding to that of the accommodation space 210. The test socket 300 may include a mounting portion in which the semiconductor device, i.e., a test target, is accommodated. Hereinafter, the test socket 300 will be described in more detail, with reference to FIG. 6 together with FIG. 7 illustrating a cross-section view taken along line I-I′ of FIG. 6.

Referring to FIG. 7, the test socket 300 may be mounted on the stiffener 200. The stiffener 200 mounted on the housing 101 may be separated from an upper surface of the circuit board 103 by at least a predetermined distance. A distance between a lower surface of the stiffener 200 and an upper surface of the circuit board 103 may be determined, such that interference between the stiffener 200 and circuit devices disposed on the upper surface of the circuit board 103 may reduced or eliminated.

The test socket 300 may include a housing 310 and a mounting portion 320, and the mounting portion 320 may extend from the housing 310. In a state in which the test socket 300 is mounted, an upper surface of the housing 310 and an upper surface of the stiffener 200 may form a generally coplanar surface. The mounting portion 320 may provide an accommodation space 305 in which the semiconductor device is to be mounted.

A plurality of holes H may be formed in a lower surface of the mounting portion 320. The plurality of holes H may correspond to the plurality of socket pins 105 formed in the first socket region 104 of the circuit board 103. For example, the plurality of socket pins 105 may be accommodated in the plurality of holes H.

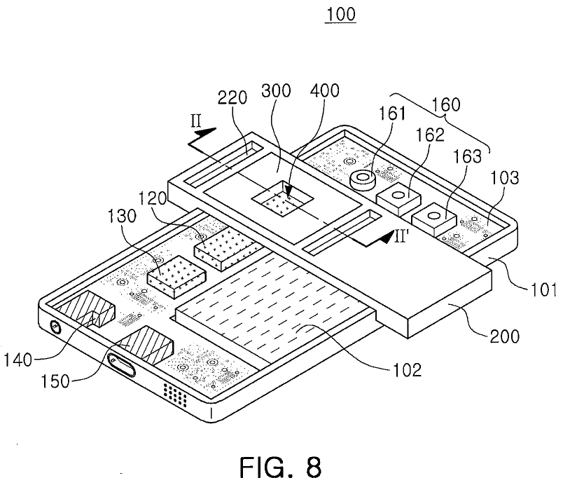

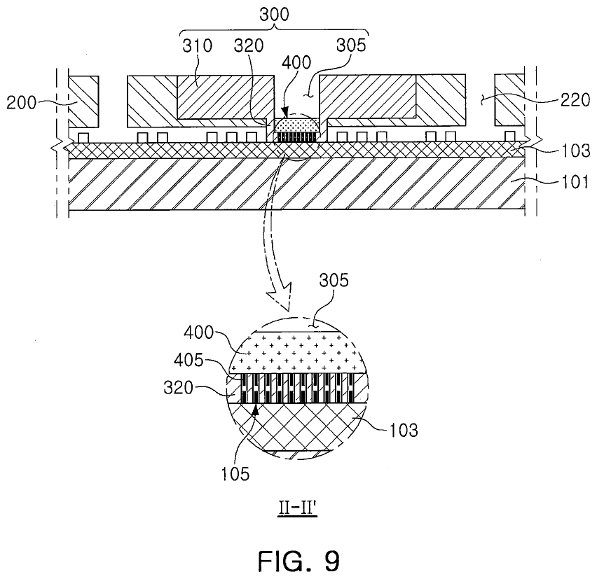

Referring to FIG. 8, a semiconductor device 400 to be tested may be mounted in an accommodation space 305 provided by a mounting portion 320 of a test socket 300. A plurality of pins may be formed on a lower surface of the semiconductor device 400, and the plurality of pins may correspond to a plurality of holes H formed in a lower surface of the mounting portion 320 of the test socket 300. Hereinafter, the arrangement relationship between the semiconductor device 400, the test socket 300, and an electronic device 100 will be described in more detail referring to FIG. 9, which is a cross-sectional view taken along line II-II′ of FIG. 8.

Referring to FIG. 9, the semiconductor device 400 may be disposed in the accommodation space 305 of the test socket 300. The accommodation space 305 may have an area corresponding to that of the semiconductor device 400 so that the semiconductor device 400 may be generally fixed in place.

Referring to the example embodiments illustrated in FIG. 9, pins 405 of the semiconductor device 400 may correspond to socket pins 105 provided in a first socket region 104 of a circuit board 103 in each of a plurality of holes H provided on the lower surface of the mounting portion 320 of the test socket 300. In each of the plurality of holes H, the pins 405 and the socket pins 105 may face each other and may be separated from each other by a predetermined distance. For example, the pins 405 of the semiconductor device 400 and the socket pins 105 of the circuit board 103 may not be connected to each other only by the semiconductor device 400 being disposed in the accommodation space 305.

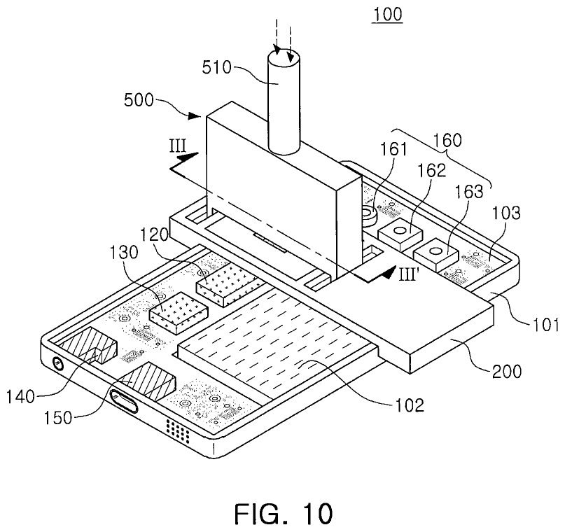

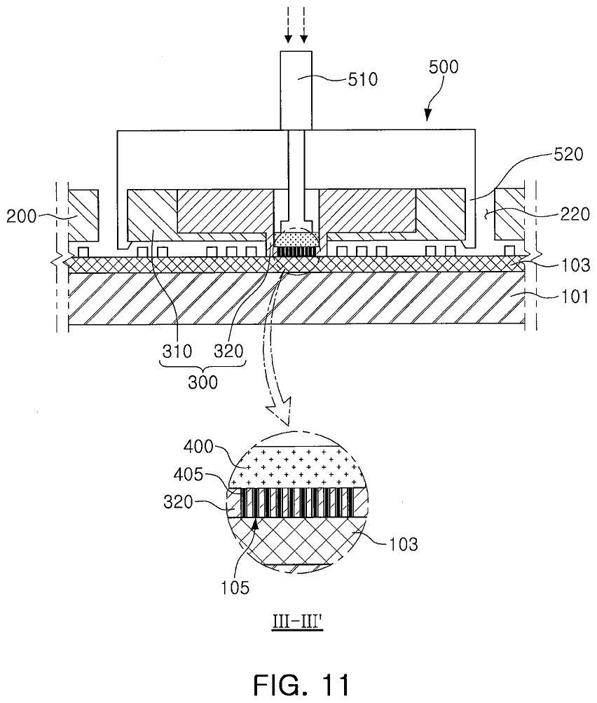

Referring to FIG. 10, a cover socket 500 may be mounted to a stiffener 200. The cover socket 500 may include a pressure portion 510 that may apply pressure to a semiconductor device. The operator who performs the test process may apply pressure to the semiconductor device 400 mounted in the test socket 300 by manipulating the pressure portion 510. As a result of the pressure, the semiconductor device 400 may move adjacently to the circuit board 103 in such a manner that the pins 405 of the semiconductor device 400 and the socket pins 105 of the circuit board 103 may contact each other, which will be described in more detail with reference to FIG. 11.

FIG. 11 is a cross-sectional view taken along line of FIG. 10. Referring to FIG. 11, the cover socket 500 may be coupled to the stiffener 200 by a fixing portion 520, and a lower portion of the pressure portion 510 may contact the semiconductor device 400. When an operator who performs a test process applies pressure to the semiconductor device 400 by manipulating the pressure portion 510, the pins 405 formed below the semiconductor device 400 may make contact with the pins 105 provided on the upper surface of the circuit board 103. Accordingly, the semiconductor device 400 and the circuit board 103 may be connected to each other in a pin-to-pin manner with the test socket 300 interposed therebetween, and the semiconductor device 400 may be configured in a state of being mounted in the first socket region 104 of the circuit board 103.

As illustrated in FIGS. 10 and 11, when the semiconductor device 400 and the circuit board 103 are connected by using the cover socket 500, a test signal may be input to the semiconductor device 400 through the circuit board 103. The semiconductor device 400 may process the received test signal and may output a result signal responsive to the test signal. In the test process, the semiconductor device 400 may be verified using a method, such as comparing a result signal output from the semiconductor device 400 with a predetermined reference signal.

In the method embodiments described with reference to FIGS. 4 to 11, the stiffener 200 fixed to the housing 101 and the test socket 300 mounted on the stiffener 200 are used without using a separate intermediate board or the like in performing a test process on the semiconductor device 400. Therefore, an operation performed to align the intermediate board and the semiconductor device 400 may be omitted and efficiency of the test process may be improved. In addition, by omitting the intermediate board, signal loss and impedance matching error caused by the intermediate board may be significantly reduced, thereby improving accuracy and reliability of the test process.

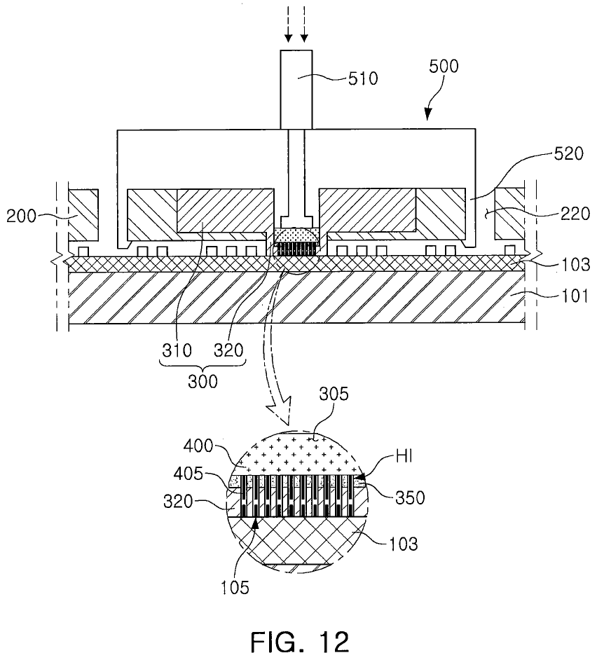

Next, referring to FIG. 12, an intermediate insulating layer 350 may be disposed between the semiconductor device 400 and the test socket 300. In some embodiments, the intermediate insulating layer 350 may be formed of an insulating material different from a material of the test socket 300, for example, rubber or the like. The intermediate insulating layer 350 may include a plurality of intermediate holes HI corresponding to the plurality of holes H formed in the lower surface of the mounting portion 320 of the test socket 300. As an example, the plurality of holes H and the plurality of intermediate holes HI may correspond to each other in one-to-one manner.

When pressure is applied to the semiconductor device 400 by the cover socket 500 mounted on the stiffener 200, the intermediate insulating layer 350 may be pressed, such that the pins 405 of the semiconductor device 400 are connected to the socket pins 105 of the circuit board 103. In the process of manufacturing the semiconductor device 400, the positions of the plurality of pins 405 may vary slightly due to manufacturing tolerances of the semiconductor device 400. In a case in which the semiconductor device 400 and the circuit board 103 are directly connected to each other with the test socket 300 interposed therebetween, the pins 405 of the semiconductor device 400 and the socket pins 105 of the circuit board 103 may not be accurately connected to each other due to manufacturing tolerances.

Such a problem may be at least partially mitigated or prevented by the intermediate insulating layer 350. The intermediate insulating layer 350 is formed of a material, such as rubber or the like having fluidity, and the intermediate insulating layer 350 is disposed between the semiconductor device 400 and the test socket 300, thereby compensating for a position change of the pins 405 due to manufacturing tolerances. Accordingly, the semiconductor device 400 may be stably coupled to the first socket region 104 of the circuit board 103, and reliability and accuracy of the test process may be improved.

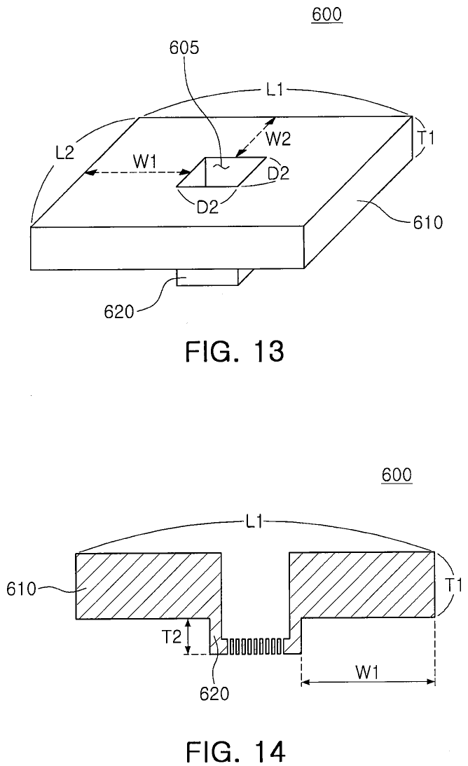

FIGS. 13 to 15 are diagrams illustrating a test socket according to example embodiments of the inventive concept.

Referring to FIGS. 13 to 15, a test socket 600 according to an example embodiment may be formed of an insulating material having a dielectric constant of 3.0 or more. As an example, the test socket 600 may be formed of bakelite obtained, for example, by condensing phenol and formaldehyde.

First, referring to FIG. 13, the test socket 600, according to some example embodiments, may include a housing 610 and a mounting portion 620 extending from the housing 610. The test socket 600 may provide an accommodation space 605 extending from the housing 610 to the mounting portion 620, and a semiconductor device to be tested may be accommodated in the accommodation space 605.

In an example embodiment illustrated in FIG. 13, the housing 610 is illustrated as having a rectangular shape defined by a first edge L1 and a second edge L2 on a plane, but the shape of the housing 610 is not limited thereto. The shape of the housing 610 on the plane may be variously modified, and as an example, the housing 610 may have a shape symmetrical with respect to the accommodation space 605 in some embodiments. According to other example embodiments, the housing 610 may have various shapes, such as a square, an ellipse, a circle, a hexagon, an octagon and the like on a plane.

The sizes of the housing 610, the mounting portion 620, and the accommodation space 605 may be determined by the size of the semiconductor device to be tested. As an example, in the case of the housing 610, the first edge L1 may be longer than the second edge L2, and the second edge L2 may be 0.5 or more of the length of the first edge L1. In other embodiments, the first edge L1 and the second edge L2 may have substantially the same length. The first edge L1 may be two or more times a length of the first edge D1 of the accommodation space 605. The first edge L1 and the second edge L2 may be respectively defined as follows. For example, each of a first distance W1 and a second distance W2 may be 1 centimeter or more in the Equation 1 set forth below. By setting the first distance W1 and the second distance W2 to 1 centimeter or more, rigidity sufficient to press the semiconductor device mounted in the accommodation space 605 by the cover socket may be realized.

L1=D1+2*W1

L2=D2+2*W2 [Equation 1]

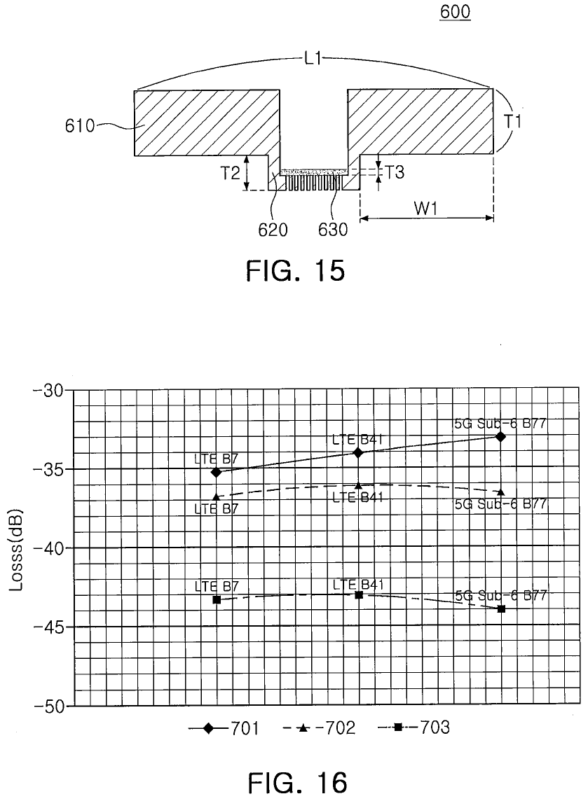

FIGS. 14 and 15 are cross-sectional views illustrating a cross section of the test socket 600 according to the example embodiments illustrated in FIG. 13. Referring to FIG. 14, the housing 610 of the test socket 600 may have a first thickness T1, and the mounting portion 620 may have a second thickness T2. In an example embodiment, the second thickness T2 may be equal to or less than the first thickness T1. The second thickness T2 may be variously determined based on the specification of the semiconductor device to be tested, which is accommodated in the accommodation space 605 in the mounting portion 620. According to some example embodiments, the second thickness T2 may be greater than the first thickness T1.

While the test socket 600 is attached to the circuit board and the test process proceeds, the second thickness T2 may be determined to have a value, such that little or no interference occurs between other circuit devices mounted on the circuit board and the housing 610 of the test socket 600. If the second thickness T2 is excessively small, when the test socket 600 is attached to the circuit board, interference may occur in a case in which a lower surface of the housing 610 contacts other circuit devices mounted on the circuit board.

A plurality of holes may be provided in a lower surface of the mounting portion 620. As described above, the plurality of holes may correspond to a plurality of pins provided on one surface of the semiconductor device to be tested. The arrangement of the plurality of holes and the number of the plurality of holes may be based on the plurality of pins included in the semiconductor device to be tested.

Referring to FIG. 15, an intermediate insulating layer 630 may be added to the accommodation space 605 of the test socket 600. The intermediate insulating layer 630 may be formed of an insulating material different from that of the test socket 600, for example, rubber or the like. The intermediate insulating layer 630 may include a plurality of intermediate holes, and the plurality of intermediate holes included in the intermediate insulating layer 630 may correspond to a plurality of holes provided in a lower surface of the mounting portion 620. In an example embodiment, a thickness T3 of the intermediate insulating layer 630 may be substantially the same as a thickness of the semiconductor device accommodated in the mounting portion 620.

For example, when the semiconductor device to be tested is mounted in the accommodation space 605 and pressure is applied to the semiconductor device by the cover socket, the plurality of pins provided on one surface of the semiconductor device may penetrate through the plurality of holes included in the intermediate insulating layer 630 and then enter the plurality of holes provided in the lower surface of the mounting portion 620. The plurality of pins provided on one surface of the semiconductor device may be connected to the socket pins provided in the socket region of the circuit board in the plurality of holes provided in the lower surface of the mounting portion 620.

FIG. 16 is a graph illustrating the effect of a test process using a test socket according to example embodiments of the inventive concept.

In an example embodiment illustrated in FIG. 16, first comparative example 701 may provide signal loss data measured when a semiconductor device to be tested is directly mounted in a socket region of a circuit board. Second comparative example 702 may provide signal loss data measured when a semiconductor device to be tested is connected with a socket region of a circuit board using an intermediate board. Embodiment 703 may provide signal loss data measured when a semiconductor device to be tested is mounted in a test socket and is directly connected with the socket region of the circuit board in a pin-to-pin manner, as in the method according to example embodiments of the present inventive concept.

The graph illustrated in FIG. 16 illustrates signal loss data occurring when a semiconductor device to be tested receives signals in an LTE B7 frequency band, an LTE B41 frequency band, and a 5G Sub-6 B77 frequency band, respectively. The LTE B7 frequency band may be a band of about 2.6 GHz, and the LTE B41 frequency band may be a band of about 2.5 GHz. The 5G Sub-6 B77 frequency band may be a band of 6 GHz or lower, for example, about 3.6 GHz.

Referring to FIG. 16, the signal loss may be relatively high in the second comparative example 702 as compared with the first comparative example 701 in which the semiconductor device is directly mounted on the circuit board. As an example, in the LTE B7 frequency band, the second comparative example 702 may have higher signal loss by about 8 dB as compared to the first comparative example 701. The second comparative example 702 may have higher signal loss than the first comparative example 701, even in the LTE B41 frequency band and the 5G Sub-6 B77 frequency band, respectively. Compared with the first comparative example 701, the second comparative example 702 may exhibit a signal loss greater by 9 dB in the LTE B41 frequency band and by 11 dB in the 5G Sub-6 B77 frequency band. Therefore, as the frequency used to exchange data increases, the signal loss illustrated in the second comparative example 702 may increase.

Meanwhile, in embodiment 703, in which the semiconductor device and the circuit board are directly connected in a pin-to-pin manner in a test socket without an intermediate board, signal loss may be relatively lower than that of the second comparative example 702. Referring to FIG. 16, the signal loss of embodiment 703 in the LTE B7 frequency band may be higher by about 1.5 dB than that of the first comparative example 701. For example, the signal loss of embodiment 703 in the LTE B7 frequency band may be lower by about 6.5 dB than that of the second comparative example 702.

The signal loss of embodiment 703 may be lower by about 7 dB in the LTE B41 frequency band and may be lower by about 7.5 dB in the 5G Sub-6 B77 frequency band than that of the second comparative example 702. Therefore, in embodiment 703 in which the semiconductor device and the circuit board are directly connected in a pin-to-pin manner in a test socket without an intermediate board, a test process based on transmitting and receiving data using an increasingly higher frequency band may be implemented with generally high reliability: In addition, because the semiconductor device and the circuit board are connected using only a test socket without an intermediate board, the cost of the test process may be lowered and process efficiency may be improved.

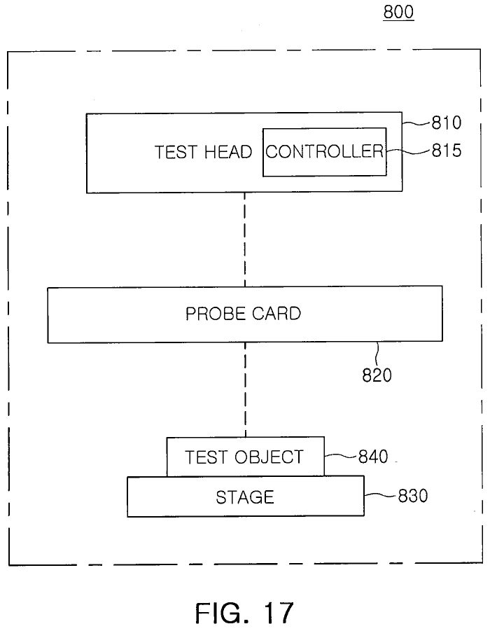

FIG. 17 is a block diagram schematically illustrating a test device according to example embodiments of the inventive concept.

Referring to FIG. 17, a test device 800 according to some example embodiments may include a test head 810, a probe card 820, a stage 830, and the like. A test object 840 may be seated on the stage 830, and the stage 830 may secure the test object 840 during the test process. In an example embodiment, the stage 830 may include an electrostatic chuck.

In the example embodiment illustrated in FIG. 17, the test object 840 may be a semiconductor wafer including a plurality of semiconductor devices. The test object 840 may be a semiconductor wafer in which a manufacturing process is almost completed. For example, the plurality of semiconductor devices included in the test object 840 may be in a state in which manufacturing is completed, such that intended functions may be executed.

The probe card 820 may receive a test signal from the test head 810 and transmit the test signal to the plurality of semiconductor devices. The probe card 820 may include a main circuit board, a test socket mounted on the main circuit board and coupled to the test object 840, and the like. In an example, the test socket may provide a plurality of accommodation spaces corresponding to the plurality of semiconductor devices. A plurality of holes may be provided in each of the plurality of accommodation spaces to correspond to a plurality of pins formed in the semiconductor device. A plurality of probe pins extending from the main circuit board of the probe card 820 may be received in the plurality of holes.

As an example, at least one of the probe card 820 and the stage 830 may move to join the test socket of the probe card 820 with the test object 840 seated on the stage 830. In other words, a plurality of semiconductor devices included in the test object 840 may be received in the plurality of accommodation spaces provided in the test socket.

The semiconductor wafer provided to the test object 840 may be provided in a state in which a scribing process is completed, such that the plurality of semiconductor devices may be accommodated in the plurality of accommodation spaces provided by the test socket. For example, the plurality of semiconductor devices included in the test object 840 may be seated on the stage 830 in a bare chip state in which they are separated from each other by a scribing process. Therefore, the test socket and the plurality of semiconductor devices may be coupled by the spaces formed between the plurality of semiconductor devices.

Pressure may be applied to at least one of the stage 830 and the probe card 820 in a state in which the plurality of semiconductor devices are accommodated in the plurality of accommodation spaces provided in the test socket. Accordingly, the plurality of pins provided in each of the plurality of semiconductor devices and the plurality of probe pins extending from the main circuit board of the probe card 820 may be connected to each other in each of the plurality of accommodation spaces of the test socket.

When the test process starts, a controller 815 of the test head 810 may generate a test signal and transmit the test signal to the probe card 820. The main circuit board of the probe card 820 may process the received test signal and transmit the received test signal to the plurality of semiconductor devices, and obtain or receive a result signal output by the plurality of semiconductor devices in response to the test signal. The controller 815 may verify each of the plurality of semiconductor devices based on the result signal according to a test standard.

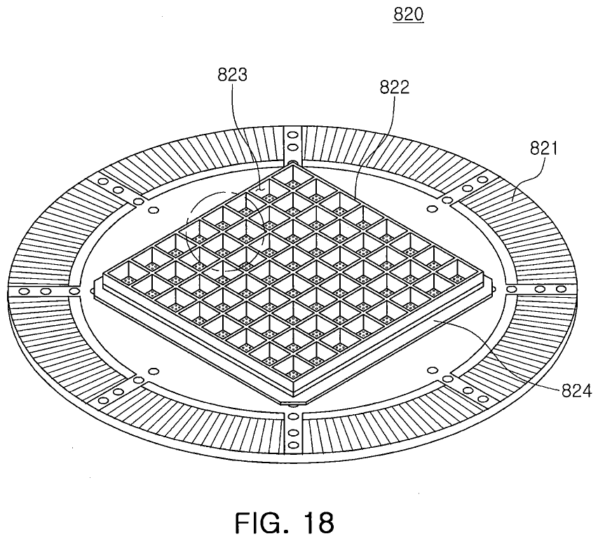

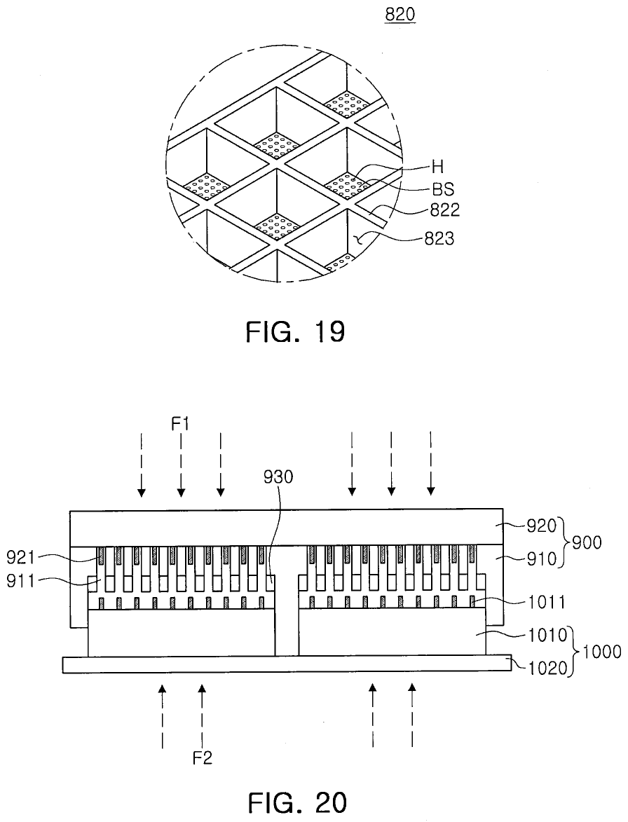

FIGS. 18 and 19 are schematic views illustrating a probe card according to example embodiments of the inventive concept.

Referring to FIG. 18, a probe card 820, according to an example embodiment, may include a main circuit board 821, a test socket 822, an auxiliary circuit board 824, and the like. The test socket 822 may be formed of an insulating material having a dielectric constant of 3.0 or more, such as bakelite or the like, and may provide a plurality of accommodation spaces 823 in which the semiconductor devices to be tested are mounted.

The main circuit board 821 may be electrically connected to the test head, and may receive a test signal generated by the controller of the test head. The main circuit board 821 may transmit a test signal to a plurality of probe pins provided in the plurality of accommodation spaces 823 provided by the test socket 822.

In an example embodiment, the test signal transmitted by the main circuit board 821 may also be transmitted to the plurality of probe pins through the auxiliary circuit board 824. The auxiliary circuit board 824 may include a multilayer ceramic substrate, and the like, and may include circuit patterns electrically connecting the plurality of probe pins provided in the test socket 822 to the main circuit board 821. According to some example embodiments, the auxiliary circuit board 824 may be omitted.

FIG. 19 is an enlarged view of a portion of the test socket 822 in the probe card 820 illustrated in FIG. 18 according to some example embodiments of the inventive concept. Referring to FIG. 19, the test socket 822 may provide the plurality of accommodation spaces 823, and the plurality of accommodation spaces 823 may be separated from each other by a partition structure. A plurality of holes H may be provided in a lower surface BS of each of the plurality of accommodation spaces 823.

Probe pins extending from the main circuit board 821 or the auxiliary circuit board 824 may be disposed in the plurality of holes H. A height of each of the probe pins may be less than a depth of the plurality of holes H in such a manner that one end of each of the probe pins may not be exposed to the outside of the test socket 822.

FIG. 20 is a view illustrating a test process using a probe card according to some example embodiments of the inventive concept.

Referring to FIG. 20, a probe card 900 may include a test socket 910, a main circuit board 920, an intermediate insulating layer 930, and the like. As described above with reference to FIGS. 18 and 19, the test socket 910 may provide a plurality of accommodation spaces, and semiconductor devices 1010 in a bare chip state may be accommodated in the plurality of accommodation spaces. A plurality of holes 911 may be provided in each of the plurality of accommodation spaces provided by the test socket 910.

The intermediate insulating layer 930 may be disposed in each of the plurality of accommodation spaces. The intermediate insulating layer 930 may be formed of an insulating material different from that of the test socket 910. As an example, the test socket 910 may be formed of bakelite, and the intermediate insulating layer 930 may be formed of a material, such as rubber or the like, having elasticity and fluidity. By including the intermediate insulating layer 930, positional errors of the pins 1011 of the semiconductor device due to manufacturing tolerances when pins 1011 of the semiconductor device 1010 and probe pins 921 of the probe card 900 are coupled may be reduced or prevented.

The main circuit board 920 may include a test circuit that receives a test signal from a test head or the like and transmits the test signal to the semiconductor devices 1010. The main circuit board 920 may include a plurality of the probe pins 921, which output a test signal, and the plurality of probe pins 921 may be accommodated in the plurality of holes 911 included in the test socket 910. As illustrated in FIG. 20, a length of the plurality of probe pins 921 may be less than a depth of the plurality of holes 911. Therefore, the plurality of probe pins 921 may be accommodated in the plurality of holes 911 and may not be exposed externally.

A test object 1000 may include semiconductor devices 1010 in a bare chip state, a tape 1020 to which the semiconductor devices 1010 are attached, and the like. As an example, the test object 1000 as illustrated in FIG. 20 may be formed according to some embodiments by performing a scribing process on a semiconductor wafer to which the tape 1020 is attached to separate the semiconductor devices 1010 in a bare chip state.

When the semiconductor devices 1010 are attached to the plurality of accommodation spaces, first pressure F1 may be applied from the upper portion of the probe card 900, and/or second pressure F2 may be applied from the lower portion of the test object 1000. The pins 1011 of the semiconductor devices 1010 and the probe pins 921 of the probe card 900 are connected to each other in a pin-to-pin manner in the plurality of holes 911 in response to the first pressure F1 and the second pressure F2. A test process on the plurality of semiconductor devices 1010 provided in a bare chip state may be performed at once using the probe card 900.

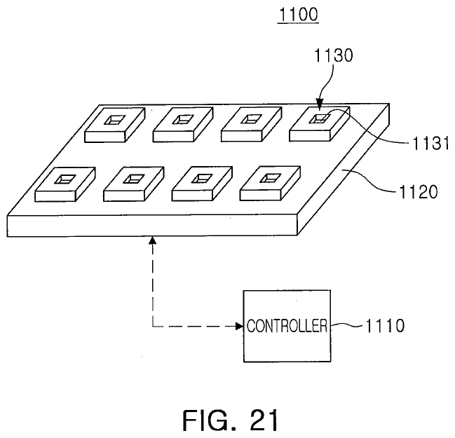

FIG. 21 is a diagram schematically illustrating a test device according to example embodiments of the inventive concept.

Referring to FIG. 21, a test device 1100 according to some example embodiments may comprise automatic test equipment (ATE). The test device 1100 may include a controller 1110 configured to generate a test signal and to perform an overall test process, an interface board 1120, test sockets 1130, and the like. A plurality of test sockets 1130 may be provided on the interface board 1120, and a device under test (DUT) may be mounted in the test sockets 1130. The device under test may be a packaged semiconductor device in some embodiments.

The controller 1110 may be configured to generate a test signal used to test the device under test and may be configured to transmit the test signal to the interface board 1120. The interface board 1120 may be configured to output a test signal to the device under test mounted in the test sockets 1130. When the device under test generates a result signal in response to the test signal, the controller 1110 may obtain or receive a result signal through the interface board 1120 and may verify the device under test, based on the result signal, according to a test standard.

In some example embodiments, the test sockets 1130 may be formed of an insulating material having a dielectric constant of 3.0 or more. For example, the test sockets 1130 may be formed of bakelite. Each of the test sockets 1130 may provide an accommodation space 1131 in which the device under test is accommodated. A plurality of holes may be provided in the accommodation space 1131, and socket pins extending from the interface board 1120 may be accommodated in the plurality of holes. The length of the socket pins may be less than the depth of the plurality of holes, and the socket pins may not be externally exposed outside of the plurality of holes.

When the device under test is received in an accommodation space 1131 of each of the test sockets 1130, pressure may be applied to the device under test by a cover socket mounted on the test sockets 1130. When pressure is applied to the device under test, pins included in the device under test may be connected to the socket pins in the plurality of holes. Therefore, the test signal generated by the controller 1110 and transmitted to the interface board 1120 may be input to the device under test.

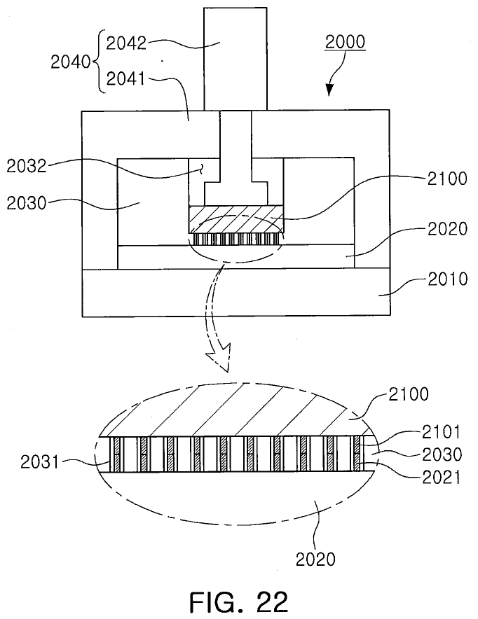

FIGS. 22 to 24 are views illustrating a test process performed in a test device according to example embodiments of the inventive concept.

In example embodiments illustrated in FIGS. 22 to 24, a test device 2000 may comprise automatic test equipment as described above with reference to FIG. 21. Referring to FIG. 22, the test device 2000 may include an interface board 2010, a socket region 2020 provided on the interface board 2010, a test socket 2030 coupled to an upper portion of the socket region 2020, a cover socket 2040 coupled to the test socket 2030, and the like. The socket region 2020 may provide a plurality of socket pins 2021 as illustrated in FIG. 22. The socket pins 2021 may extend upwardly from the socket region 2020.

The test socket 2030 may be formed of a material having a dielectric constant of 3.0 or more, for example, bakelite or the like, and may be coupled to the socket region 2020. The test socket 2030 may include a plurality of holes 2031 accommodating the socket pins 2021, and may provide an accommodation space 2032 in which a device under test 2100 is accommodated.

When the device under test 2100 is accommodated in the accommodation space 2032, the cover socket 2040 may be coupled to an upper portion of the test socket 2030. The cover socket 2040 may include a main body 2041 and a pressure portion 2042, and the pressure portion 2042 may descend to apply pressure to the device under test 2100. When pressure is applied to the device under test 2100 while the pressure portion 2042 descends, pins 2101 of the device under test 2100 and the socket pins 2021 of the socket region 2020 may make contact with each other in the plurality of holes 2031.

The test device 2000 may be configured to output a test signal to the device under test 2100 through the interface board 2010 in a state in which pressure is applied to the device under test 2100 using the pressure portion 2042. When the device under test 2100 outputs a result signal in response to the test signal, the result signal may be used to verify whether the device under test is defective based on a test standard.

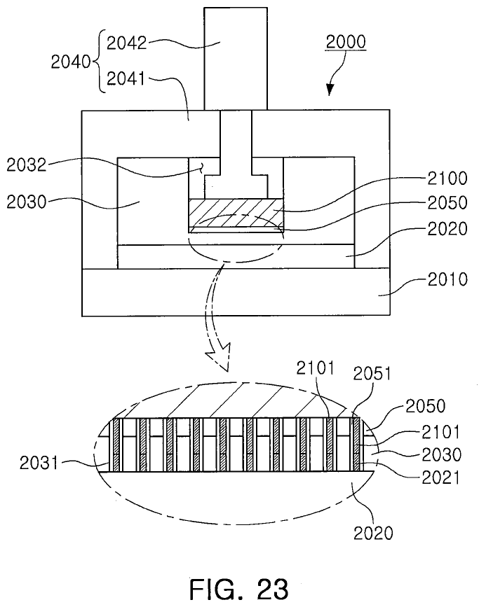

Next, referring to FIG. 23, an intermediate insulating layer 2050 may be inserted between the device under test 2100 and the test socket 2030. The intermediate insulating layer 2050 may be formed of an insulating material, such as rubber, having elasticity and/or fluidity, or the like, and may have a plurality of intermediate holes 2051 corresponding to the socket pins 2031. For example, the plurality of intermediate holes 2051 may correspond to the plurality of holes 2031 included in the test socket 2030.

When the cover socket 2040 is coupled with the test socket 2030 and pressure is applied to the device under test 2100, the intermediate insulating layer 2050 is compressed to connect the pins 2101 of the device under test 2100 to the socket pins 2021 of the socket region 2020. By inserting the intermediate insulating layer 2050 having elasticity and/or flowability, positional errors of the pins 2101 that may exist in the device under test 2100 due to manufacturing tolerances may be compensated for; as a result, reliability of the test process may be improved.

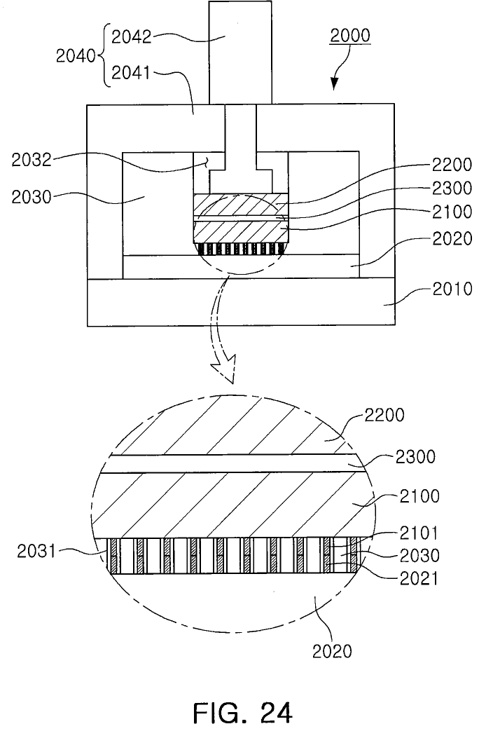

Referring to FIG. 24, a device under test may include a first semiconductor device 2100, a second semiconductor device 2200, a coupling guide layer 2300 and the like. The coupling guide layer 2300 may couple the first semiconductor device 2100 to the second semiconductor device 2200 and the resulting assembly may be shipped as a single semiconductor package.

In an example embodiment illustrated in FIG. 24, the first semiconductor device 2100 and the second semiconductor device 2200 may not be coupled while the test device 2000 performs the test process. For example, the first semiconductor device 2100, the coupling guide layer 2300, and the second semiconductor device 2200 may be sequentially received in the accommodation space 2032 provided by the test socket 2030, and then the test process may be performed under pressure applied by the cover socket 2040.

In other words, in a state in which manufacture or assembly of the semiconductor package is not completed before final shipment, a test process may be performed before a semiconductor packaging process in which the first semiconductor device 2100 and the second semiconductor device 2200 are coupled. Therefore, when one of the first semiconductor device 2100 and the second semiconductor device 2200 is determined to be defective, a device that is determined to be of good quality may be moved to a package manufacturing process excluding the device determined to be defective. As a result, by performing a test process in a state in which manufacture or assembly of the semiconductor package is not completed before final shipment, an overall yield of the manufacturing process may be improved.

As set forth above, according to example embodiments of the inventive concept, a test socket may be formed of an insulating material, such as bakelite. Pins of a semiconductor device and pins of a circuit board are connected to each other in a plurality of holes formed in a lower surface of a mounting portion to which the semiconductor device is fixed in the test socket. The semiconductor device and the circuit board may be electrically coupled in a plurality of holes provided by the test socket without a separate intermediate circuit board, thereby significantly reducing signal loss and providing impedance improved impedance matching, and, thus, improving reliability and efficiency of a test process for a semiconductor device.

While example embodiments have been illustrated and described above, it will be apparent to those skilled in the art that modifications and variations could be made without departing from the scope of the present inventive concept as defined by the appended claims.

What is claimed is:

1. A test socket, comprising:
a housing; and
a mounting portion extending from the housing and comprising an accommodation space configured to mount a semiconductor device thereon,
wherein a lower surface of the mounting portion comprises a plurality of holes corresponding to a plurality of pins included in the semiconductor device, the plurality of holes being configured to align the plurality of pins of the semiconductor device with a plurality of socket pins of a printed circuit board, and
wherein the housing and the mounting portion comprise a same insulating material.

2. The test socket of claim 1, wherein the housing and the mounting portion comprise bakelite.

3. The test socket of claim 1, wherein a dielectric constant of the insulating material is 3.0 or more.

4. The test socket of claim 1, wherein an upper surface of the housing has a shape symmetrical with respect to a first axis corresponding to a first direction and with respect to a second axis corresponding to a second direction intersecting the first direction.

5. The test socket of claim 4, wherein the upper surface of the housing comprises a first edge extending in the first direction and a second edge extending in the second direction, and a length of the first edge is greater than a length of the second edge.

6. The test socket of claim 5, wherein the length of the second edge is at least 0.5 times the length of the first edge.

7. The test socket of claim 1, wherein a number of the plurality of holes is equal to a number of the plurality of pins included in the semiconductor device.

8. The test socket of claim 1, wherein a length of the mounting portion in a direction in which the mounting portion extends from the housing is greater than a height of circuit devices mounted on an upper surface of the printed circuit board.

9. The test socket of claim 1, wherein a height of the accommodation space in a direction perpendicular to an upper surface of the printed circuit board is greater than a thickness of the semiconductor device in the direction perpendicular to the upper surface of the printed circuit board.

10. A probe card comprising:
a test socket comprising a material having a dielectric constant of 3.0 or more and having a plurality of accommodation spaces separated from each other by a partition structure to accommodate a plurality of semiconductor devices, respectively, a lower surface of each of the plurality of accommodation spaces having a plurality of holes corresponding to a plurality of pins included in each of the plurality of semiconductor devices; and
a main circuit board on one surface of the test socket and electrically connected to a test device, the main circuit board including a plurality of probe pins extending therefrom into the plurality of holes included in each of the plurality of accommodation spaces, respectively.

11. The probe card of claim 10, wherein the plurality of pins and the plurality of probe pins are connected in a pin-to-pin manner in the plurality of holes.

12. The probe card of claim 10, wherein the test socket comprises bakelite.

13. The probe card of claim 10, further comprising an intermediate insulating layer between the semiconductor device and the test socket in each of the plurality of accommodation spaces.

14. The probe card of claim 13, wherein the intermediate insulating layer comprises a plurality of intermediate holes corresponding to the plurality of holes.

15. A test device comprising:
a controller configured to generate a signal for testing of a test object having at least one semiconductor device;
a test socket comprising bakelite and comprising at least one accommodation space configured to accommodate the at least one semiconductor device, the at least one accommodation space having a plurality of test pins configured to output the signal to the at least one semiconductor device; and
a cover socket configured to apply pressure to the at least one semiconductor device.

16. The test device of claim 15, further comprising a stiffener on which the test socket is mounted and to which the cover socket is attached.

17. The test device of claim 16, wherein an upper surface of the stiffener and an upper surface of the test socket are substantially coplanar with each other.

18. The test device of claim 16, wherein the stiffener is configured for attachment to a printed circuit board on which the at least one semiconductor device is mounted.

19. The test device of claim 15, wherein the test object comprises a plurality of semiconductor devices included in a semiconductor wafer, and
the test socket comprises a plurality of accommodation spaces, the plurality of accommodation spaces being configured to accommodate the plurality of semiconductor devices, respectively, and being separated from each other by a partition structure, the test socket being mounted on a main circuit board comprising a circuit configured to transmit the signal to the plurality of test pins.

20. The test device of claim 19, wherein the test socket and the main circuit board provide a probe card.
